(19) United States
(12) Patent Application Publication
(10) Pub. No.: US 2010/0038011 A1
(43) Pub. Date: Feb. 18, 2010

(54) METHOD AND MEMBER FOR RETAINING CABLE HARNESS SHAPE

(75) Inventor: Noriko Yoshinaga, Wako-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: HONDA MOTOR CO., LTD., Tokyo (JP)

(21) Appl. No.: 12/536,083

(22) Filed: Aug. 5, 2009

(30) Foreign Application Priority Data
Aug. 18, 2008 (JP) 2008-209823

(51) Int. Cl. B32B 37/00; H05K 5/02

(52) U.S. Cl. 156/85; 174/135

(57) ABSTRACT

Axial row of lateral cuts is formed in a heat-shrinkable shape retaining tube, each of the cuts extending through the wall thickness of a substantially half of the periphery of the tube. Cable harness is passed through the tube. The harness, passed through the tube, is curved by an external force being applied to the harness with the lateral cuts positioned on the outer side of the harness. The tube is then heated to a predetermined heat shrinkage temperature and hardens to present a predetermined rigidity. Thus, the harness can be retained in a desired curved shape by the tube.

### FIELD OF THE INVENTION

The present invention relates to a method for retaining a shape of a cable harness curved in two or three dimensions, and a cable harness shape retaining member.

### BACKGROUND OF THE INVENTION

Cable harnesses curved to avoid interference with other components therearound are in wide practical use today as means for interconnecting electric components of an automotive vehicle or other type of vehicle. Such cable harnesses have to be prevented from contacting other components therearound due to swinging caused by vibrations of the vehicle etc. Thus, there have been proposed a variety of techniques for preventing undesired swinging of a cable harness (see Japanese Patent Application Laid-Open Publication No. HEI-06-165341).

FIG. 6 hereof is a view explanatory of the basic principles of the technique disclosed in the HEI-06-165341 publication. A plurality of cables of a curved cable harness 101 are bundled together with harness tapes 102 at a plurality of portions thereof. Curved portion 103 of the cable harness 101 is covered with a guide 104 so as to retain the curved shape of the cable harness 101. Further, the curved cable harness 101 is fixed in place by a plurality of clips (or forks) 105. Such arrangements can retain a desired shape of the harness 101 curved in two or three dimensions.

However, because the guide 104 is a dedicated guide corresponding in shape to the harness 101 in question, a separate guide 104 has to be provided for each different curved shape of the cable harness, which would undesirably increase necessary cost. Further, many clips (forks) 105 and dedicated mounting brackets therefor are also required, which would further increase the necessary cost.

### SUMMARY OF THE INVENTION

In view of the foregoing prior art problems, it is an object of the present invention to provide an improved harness shape retaining method and an improved cable harness shape retaining member which can reliably retain a desired shape of the cable harness at reduced cost.

In order to accomplish the above-mentioned object, in one aspect, the present invention provides an improved method for retaining a shape of a cable harness curved in two or three dimensions, which comprises the steps of: providing a heat-shrinkable shape retaining tube that is adapted to permit passage therethrough of a cable harness and that has a characteristic of shrinking by being heated and presenting a predetermined rigidity after the heat shrinkage; cut-forming, in the shape retaining tube, an axial row of a plurality of lateral cuts each extending through a wall thickness of the tube and over a substantially half of the periphery of the shape retaining tube; passing the harness through the shape retaining tube having the lateral cuts formed therein by the cut-forming step; curving the harness, passed through the shape retaining tube, by applying an external force to the harness; heating the shape retaining tube, having the curved harness passed therethrough, up to a heat shrinkage temperature of the tube; and removing the external force after the heated shape retaining tube hardens to present a predetermined rigidity.

According to the present invention, the cable harness can be retained in any desired shape using the heat-shrinkable shape retaining tube. Formation of the lateral cuts in the heat-shrinkable shape retaining tube allows the same tube to be used for a variety of different curved shapes of the cable harness. Because the cable harness can be retained in any desired shape by the heat-shrinkable shape retaining tube being merely curved and heat-shrunk, the present invention can significantly reduce the necessary cost.

Preferably, in the curving step, the external force is applied to the harness with the lateral cuts of the heat-shrinkable shape retaining tube positioned on the outer side of the harness as viewed in a direction of the curving of the cable harness.

According to another aspect of the present invention, there is provided an improved cable harness shape retaining member which is in the form of a heat-shrinkable shape retaining tube that has a characteristic of shrinking by being heated and presenting a predetermined rigidity after the heat shrinkage, which has formed therein an axial row of a plurality of lateral cuts each extending through the wall thickness of the tube and over a substantially half of the periphery of the tube, and which is adapted to permit passage therethrough of a cable harness and is heated up to a heat shrinkage temperature thereof after the cable harness passed through the tube is curved into a desired shape, so that the heat-shrinkable shape retaining tube can retain the cable harness in the desired shape by hardening to present the predetermined rigidity after the heat shrinkage.

The following will describe embodiments of the present invention, but it should be appreciated that the present invention is not limited to the described embodiments and various modifications of the invention are possible without departing from the basic principles. The scope of the present invention is therefore to be determined solely by the appended claims.

### BRIEF DESCRIPTION OF THE DRAWINGS

Certain preferred embodiments of the present invention will hereinafter be described in detail, by way of example only, with reference to the accompanying drawings, in which:

FIG. 1 is a perspective view showing an embodiment of a cable harness constructed in accordance with the present invention;

FIG. 2 is an enlarged view of a section encircled at 2 in FIG. 1;

FIG. 3A-3C are views explanatory of a provision step through a harness passing step;

FIGS. 4A and 4B are views explanatory of a harness curving step through to an external force removing step;

FIG. 5 is a view explanatory of the basic principles of an embodiment of a harness shape retaining method of the present invention; and

FIG. 6 is a view explanatory of the basic principles of a conventional technique relevant to the present invention.

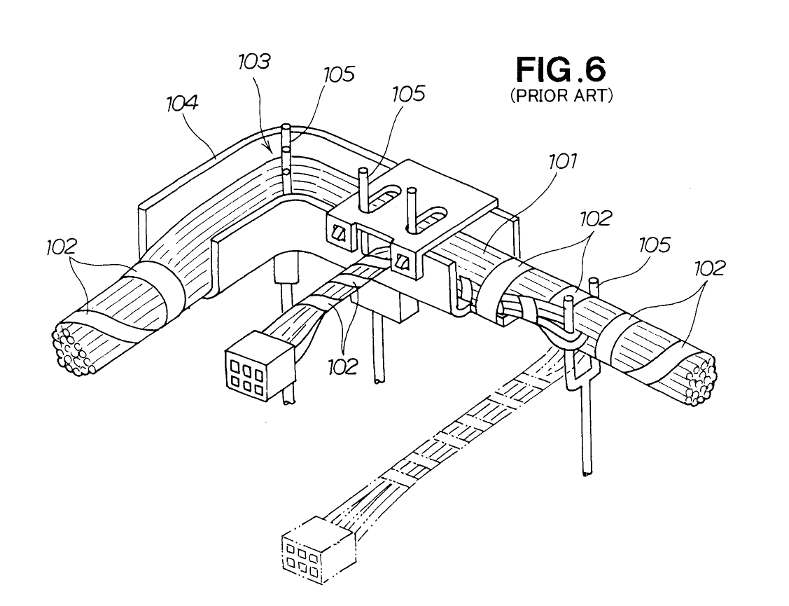

### DETAILED DESCRIPTION OF THE PREFERRED EMBODIMENTS

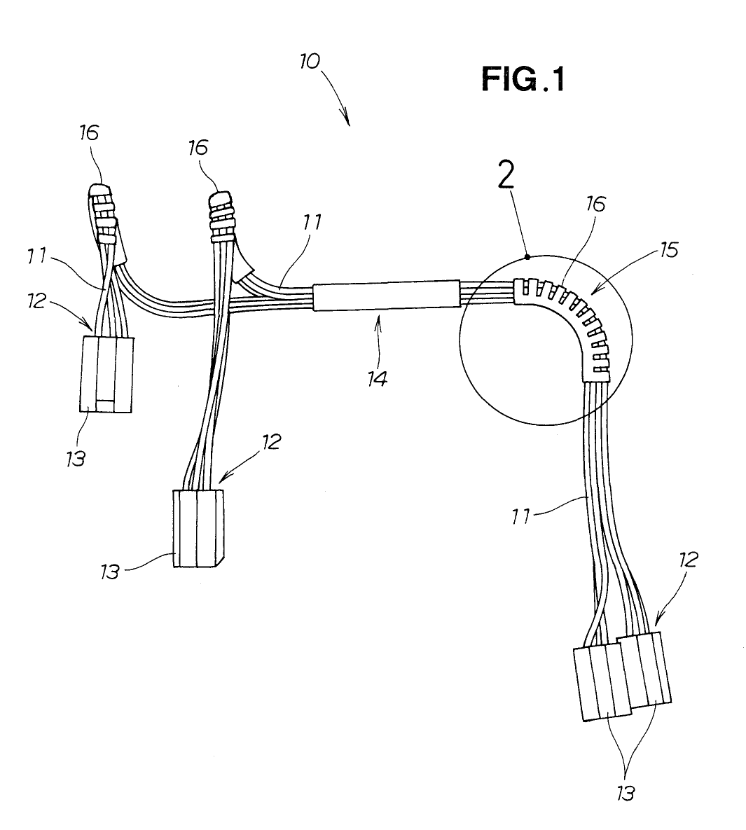

Reference is now made to FIG. 1 showing in perspective a cable harness 10 constructed in accordance with the present invention. The cable harness 10 comprises a plurality of cables 11 each comprising a sheathed group of mutually insulated conductors; and a plurality of connectors provided at the opposite ends of the cables 11 for electrically interconnecting desired electric devices or the like. A plurality of cable harness shape retaining members 16 each in the form of a tube made of a heat shrinkable material (hereinafter referred to as “heat-shrinkable shape retaining tube 16”) are provided on and around some of straight and curved sections 14 and 15 of the harness 10 for retaining the cable harness 10 in a desired curved shape, as will be detailed hereinbelow.

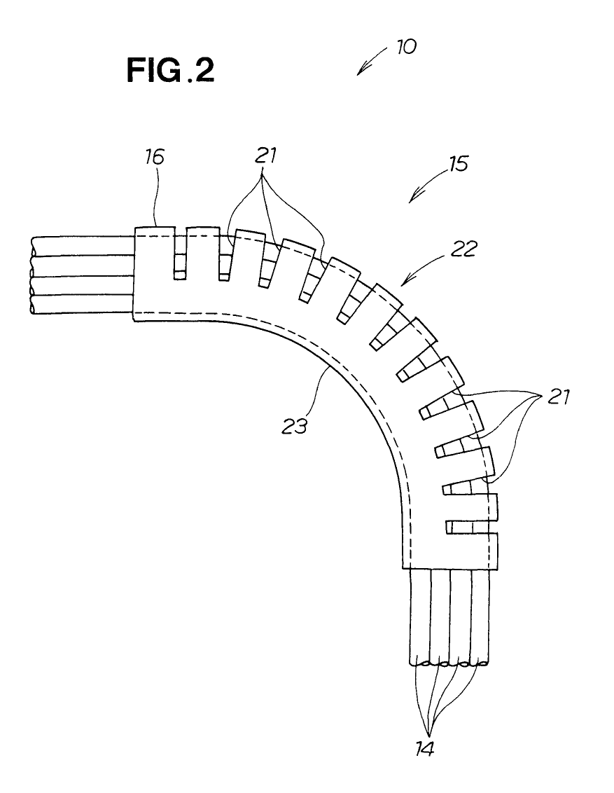

FIG. 2 is an enlarged view of a section encircled at 2 in FIG. 1, which particularly shows the heat-shrinkable shape retaining tube 16 having an axial row of lateral cuts 21 each formed through the wall thickness of the tube 16 and each extending over a substantially half of the periphery of the shape retaining tube 16. Formation of such lateral cuts 21 in the heat-shrinkable shape retaining tube 16 allows the same tube 16 to be used for a variety of different curved shapes of the cable harness. The lateral cuts 21 are located on an outer side 22 of the curved section 15 of the harness 10 and spaced apart from one another in the axial direction of the shape retaining tube 16. The heat-shrinkable shape retaining tube 16 has an axial length greater than a length of an arc 23 of the curved section 15. The shape retaining tube 16, which has a characteristic of shrinking by being heated and presenting a predetermined rigidity after the heat shrinkage, is passed over the harness 10. The shape retaining tube 16, passed over the harness 10, is heated to be shrunk and then hardens to have a predetermined rigidity after the heat shrinkage, so that it can retain the shape of the cable harness 10 curved in two or three dimensions. Thus, according to the present invention, it is possible to curve the harness 10 freely and readily into any desired shape and then retain the harness 10 in the desired curved shape by means of the shape retaining tube 16 without using any clip, mounting bracket, resin-made guide, etc. that were necessary in the past; as a result, the cable harness 10 can be retained in the desired curved shape with a simple and inexpensive construction.

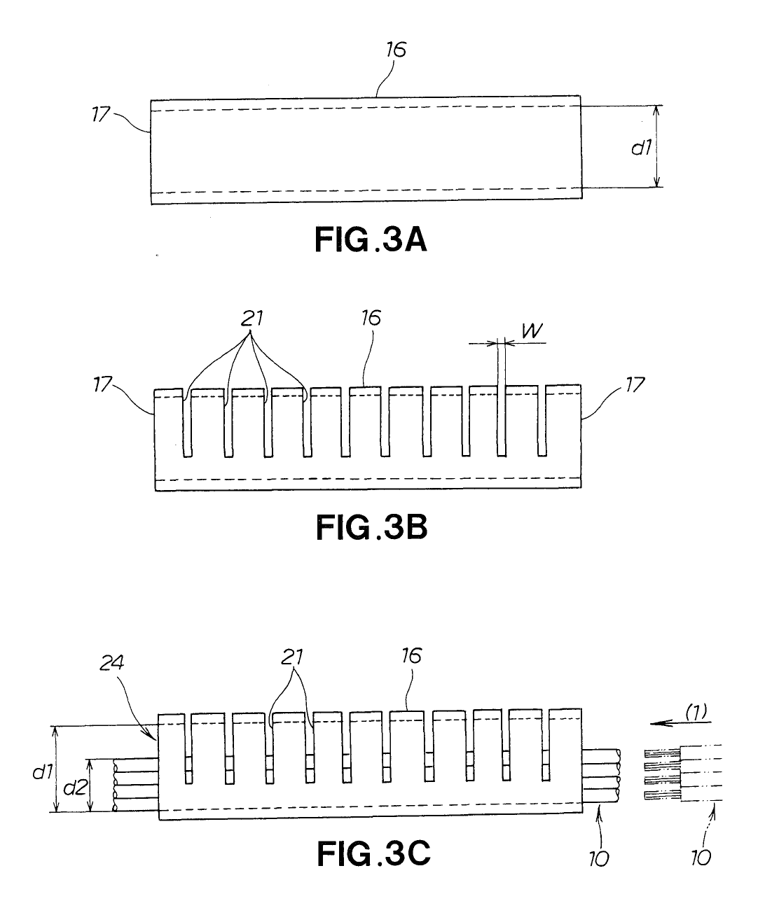

The following describe how a cable harness is retained in a desired curved shape according to the present invention. FIGS. 3A-3C are views explanatory of a provision step through a harness passing step of a harness shape retaining method of the present invention. FIG. 3A is explanatory of the provision step of providing a heat-shrinkable shape retaining tube 16 that has an inner diameter d1 to permit passage therethrough of a cable harness 10 and has a characteristic of shrinking by being heated and presenting a predetermined rigidity after the heat shrinkage. Further, the heat-shrinkable shape retaining tube 16 has an axial length greater than a length of an arc 23 of curved section 15 (see FIG. 2) of the harness 10.

Preferably, the heat-shrinkable shape retaining tube 16 is formed of electron beam cross-linking soft pre-olefin resin, and has a heat shrinkage temperature of 115° C. or over, an inner diameter shrinkage rate of 40% or over, a length change rate of −15% or more and a continuously-usable temperature (i.e., a temperature range over which the heat-shrinkable shape retaining tube 16 can be used continuously) of −55° C. to 105° C. . However, the heat-shrinkable shape retaining tube 16 may be formed of any other suitable material than the aforementioned electron beam cross-linking soft pre-olefin resin as long as it has a characteristic of shrinking by being heated and presenting a predetermined rigidity after the heat shrinkage.

FIG. 3B is a view explanatory of a cut forming step of forming an axial row of plurality of lateral cuts 21 in the heat-shrinkable shape retaining tube 16, each of the lateral cuts 21 extending over a substantially half of the periphery of the shape retaining tube 16.

FIG. 3C is a view explanatory of the passing step of passing the harness 10 through the heat-shrinkable shape retaining tube 16. As indicated by arrow (1), the harness 10 indicated by an imaginary line is passed through the heat-shrinkable shape retaining tube 16 having the lateral cuts 21 formed therein. The harness 10 has an outer diameter d2 smaller than the inner diameter d1 of the heat-shrinkable shape retaining tube 16 (i.e., d2<d1) so that a gap 24 is left between the harness 10 and the tube 16 when the cable harness 10 is passed through the shape retaining tube 16.

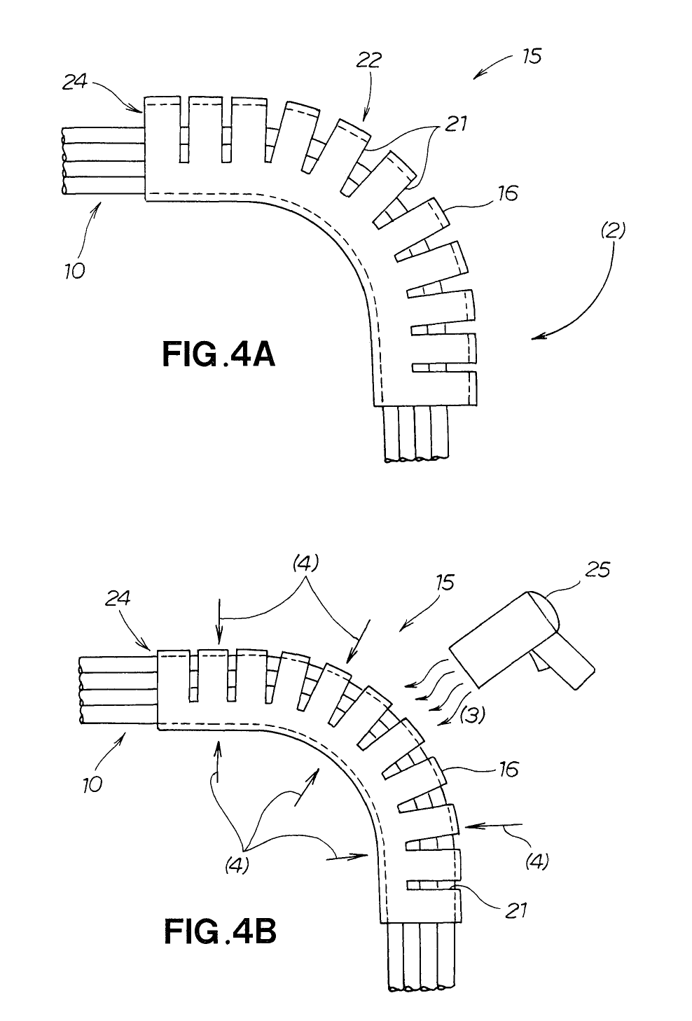

FIGS. 4A and 4B are views explanatory of a harness curving step through to an external force removing step of the harness shape retaining method of the invention. FIG. 4A is explanatory of the harness curving step, where an external force is applied to the cable harness 10 with the lateral cuts 21 positioned on the outer side (upper side in the figures) of the curved portion 15, as indicated by arrow (2), to curve the harness 10 in two or three dimensions.

FIG. 4B is explanatory of a tube heating step, where the heat-shrinkable shape retaining tube 16 passed over the cable harness 10 is heated by a heater 25 up to the heat shrinkage temperature as indicated by arrows (3). Then, the heat-shrinkable shape retaining tube 16 shrinks until the gap 24 no longer exists between the harness 10 and the tube 16, as indicated by arrows (4).

Next, the heat-shrinkable shape retaining tube 16, having heat-shrunk in the aforementioned manner, is cooled. Then, the external force is removed after the heat-shrinkable shape retaining tube 16 has hardened to present a predetermined rigidity. In this way, the shape of the cable harness 10 curved in two or three dimensions can be retained by the heat-shrinkable shape retaining tube 16.

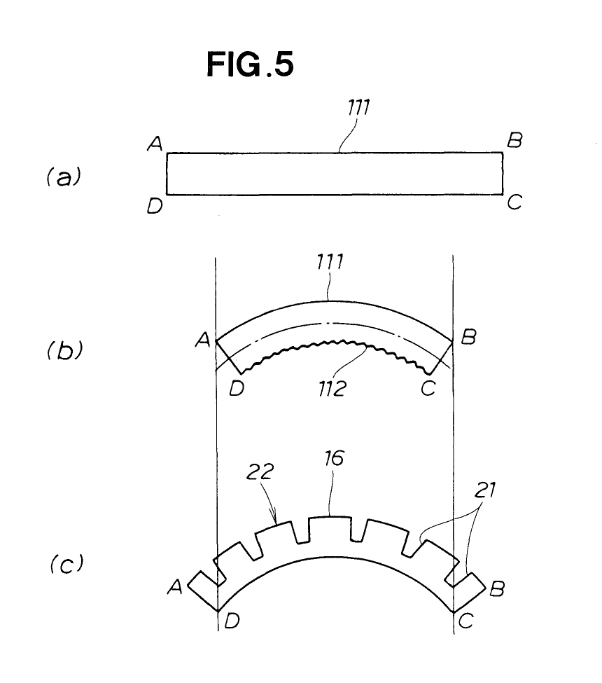

FIG. 5 is a view explanatory of the basic principles of the harness shape retaining method of the present invention, where (a) and (b) show a comparative (conventional) example of a heat-shrinkable shape retaining tube 111 having no lateral cuts therein while (c) shows an embodiment of the heat-shrinkable shape retaining tube 16 having the lateral cuts 21 therein. In (a) of FIG. 5, the tube 111 is shown, for convenience of explanation, as a mere horizontally elongated rectangle with four apexes A, B, C and D. The tube 111 is curved as a cable harness passed therethrough is curved into an upwardly arcuate shape, as shown in (b), with the side connecting the apexes C and D (i.e., side C-D) positioned on its inner side (i.e., inner side as viewed in the curving direction of the harness). Namely, in this case, the side connecting the apexes A and B (i.e., side A-B) becomes an expanding side, while the side connecting the apexes C and D becomes a shrinking side. Shrinkage of the tube 111 is absorbed by the side C-D getting wrinkled. Namely, as the tube 111 shown in (a) of FIG. 5 is curved, wrinkles 112 would be unavoidably produced in an inner side portion of the tube 111.

In the embodiment of the heat-shrinkable shape retaining tube 16 having the lateral cuts 21 on its outer side (i.e., outer side as viewed in the curving direction of the harness), as shown in (c) of FIG. 5, the lateral cuts 21 expand along the axis of the tube 16 as the tube 16 is curved into an upwardly arcuate shape. Consequently, no substantial axial compressive force is applied to the inner side C-D, so that no wrinkles are produced in an inner side portion of the tube 16. As a result, the heat-shrinkable shape retaining tube 16 as well as the cable harness can be retained in a desired three-dimensional shape even after an external restraining (or curving) force so far applied to the harness is removed.

According to the harness shape retaining method of the present invention, each of the lateral cuts 21 may have a width W (FIG. 3B) in a range of 0.01-0.1 mm or a width W of several millimeters; the width W of and intervals between the lateral cuts 21 may be chosen or set in accordance with a desired curved shape of the cable harness 10. Further, the cable harness 10 may be curved either in two dimensions or in three dimensions.

Further, although not particularly shown in the drawings, the lateral cuts 21 may be formed on the inner side of the cable harness 10, in which case the lateral cuts 21 are each formed to have a greater width W of several millimeters because, in this case, the width D decreases, rather than increases, as the harness is curved into an upwardly arcuate shape. With the lateral cuts 21 positioned on the inner side (as viewed in the direction of the curving) of the harness rather than on the outer side of the harness, the harness can have an improved outer appearance.

The harness shape retaining method and harness shape retaining member of the present invention are well suited for retaining shapes of cable harnesses curved in two or three dimensions.

What is claimed is:

1. A method for retaining a shape of a cable harness curved in two or three dimensions, comprising the steps of:
providing a heat-shrinkable shape retaining tube that is adapted to permit passage therethrough of a cable harness and that has a characteristic of shrinking by being heated and presenting a predetermined rigidity after heat shrinkage;
cut-forming, in the shape retaining tube, an axial row of a plurality of lateral cuts each extending through a wall thickness of the tune and over a substantially half of a periphery of the tube;
passing the harness through the shape retaining tube having the lateral cuts formed therein by the cut-forming step;
curving the harness, passed through the shape retaining tube, by applying an external force to the harness;
heating the shape retaining tube, having the curved harness passed therethrough, up to a heat shrinkage temperature of the tube; and
removing the external force after the heated shape retaining tube hardens to present a predetermined rigidity.

2. The method of claim 1, wherein, in the curving step, the external force is applied to the harness with the lateral cuts of the tube positioned on an outer side of the harness as viewed in a direction of the curving of the harness.

3. A cable harness shape retaining member in a form of a heat-shrinkable shape retaining tube that has a characteristic of shrinking by being heated and presenting a predetermined rigidity after heat shrinkage,
the heat-shrinkable shape retaining tube having formed therein an axial row of a plurality of lateral cuts each extending through a wall thickness of the tube and over a substantially half of a periphery of the tube,
the heat-shrinkable shape retaining tube being adapted to permit passage therethrough of a cable harness and being heated up to a heat shrinkage temperature thereof after the cable harness passed through the tube is curved into a desired shape, so that the heat-shrinkable shape retaining tube can retain the cable harness in the desired shape by hardening to present the predetermined rigidity after the heat shrinkage.
